(19) United States
(12) Patent Application Publication
(10) Pub. No.: US 2019/0019717 A1
(43) Pub. Date: Jan. 17, 2019

(54) DESIGN FOR A TESSELLATED MAGNETIC STAGE FOR THE PARALLEL ASSEMBLY OF DIAMAGNETIC COMPONENTS

(71) Applicant: SelfArray, Inc., Troy, NY (US)

(72) Inventor: Mark DURNIAK, Lafayette, CO (US)

(73) Assignee: SelfArray, Inc., Troy, NY (US)

(21) Appl. No.: 16/032,286

(22) Filed: Jul. 11, 2018

Related U.S. Application Data
(60) Provisional application No. 62/531,493, filed on Jul. 12, 2017.

(51) Int. Cl. H01L 21/683; H01L 25/075; H01L 33/62; B65G 47/92

(52) U.S. Cl. CPC H01L 21/6835; H01L 25/0753; H01L 33/62; H01L 2221/68363; H01L 2933/0066; H01L 2221/68309; B65G 47/92

(57) ABSTRACT

Systems, and methods of use thereof, for assembling a plurality of diamagnetic components. The system including a first stage and a second stage, wherein each of the first stage and the second stage include a plurality of substages, the plurality of substages arranged in a checkerboard pattern, and a plurality of openings between the plurality of substages, wherein the plurality of the substages and the plurality of the openings of the first stage are complimentary to the plurality of the substages and the plurality of the openings of the second stage.

### CROSS-REFERENCE TO RELATED APPLICATION

This application claims priority benefit under 35 U.S.C. § 119(e) to U.S. Provisional Application No. 62/531,493, filed 12 Jul. 2017, and entitled DESIGN FOR A TESSELATED MAGNETIC STAGE FOR THE PARALLEL ASSEMBLY, OF DIAMAGNETIC COMPONENTS, the entirety of which is incorporated herein by reference in its entirety.

### FIELD OF THE INVENTION

The present invention relates to a set of tessellated magnetic stages for directed self-assembly of components into a grid array and more particularly, for parallel assembly of light emitting diode (LED) dies into a grid array.

### BACKGROUND

Current methods of assembling components, such as light emitting diodes (LEDs), can be slow and unable to manipulate very small components. For larger scale displays, assembly time of LED components increases quadratically as pixel pitch decreases. The assembly time, yield, and associated machine costs can determine the overall production volume and cost of a display made using these techniques.

Therefore, it is desirable to develop techniques to increase throughput and yield, and handle components more efficiently and effectively.

### BRIEF SUMMARY

The shortcomings of the prior art are overcome and additional advantages are provided through the provisions. In one aspect, a system for assembling a plurality of diamagnetic components that includes, for instance: a first stage and a second stage, wherein each of the first stage and the second stage include a plurality of substages, the plurality of substages arranged in a checkerboard pattern, and a plurality of openings between the plurality of substages, wherein the plurality of the substages and the plurality of the openings of the first stage are complimentary to the plurality of the substages and the plurality of the openings of the second stage.

In another aspect, a method of assembling a plurality of diamagnetic components includes, for instance, depositing the plurality of diamagnetic components on a first stage and a second stage, wherein each of the first stage and the second stage include a plurality of substages, the plurality of substages arranged in a checkerboard pattern, and a plurality of openings between the plurality of substages, wherein the plurality of the substages and the plurality of the openings of the first stage are complimentary to the plurality of the substages and the plurality of the openings of the second stage, vibrating the first stage and the second stage, aligning the plurality of diamagnetic components into stable magnetic nodes of the first stage and the second stage, any non-aligned components falling off a set of edges of the first and second stages, at least some non-aligned components falling into the openings, and transferring the aligned plurality of diamagnetic components onto a transfer substrate.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a method of constructing a set of complimentary tessellated magnetic stages for directed self-assembly of a plurality of diamagnetic components and transferring them into a complete grid-array, in accordance with one or more aspects of the present invention;

FIG. 2 depicts a top view of one embodiment of a magnetic stage and the corresponding unit cell for tessellation with shaded corners, in accordance with one or more aspects of the present invention;

FIG. 3 depicts a top view of one embodiment of a set of complimentary tessellated magnetic stages, where u and v are both even, containing open holes, edge cut-outs, and missing corners, in accordance with one or more aspects of the present invention;

FIG. 4 depicts a top view of one embodiment of a set of complimentary tessellated magnetic stages, where u and v are of mixed parity, containing open holes, edge cut-outs, and missing corners, in accordance with one or more aspects of the present invention;

FIG. 5 depicts a top view of one embodiment of a set of complimentary tessellated magnetic stages, where u and v are both odd, containing open holes, edge cut-outs, and missing corners, in accordance with one or more aspects of the present invention;

FIGS. 6A and 6B depict a top view of one embodiment of a set of complimentary tessellated magnetic stages and the sets of corresponding grid points, X and Y, which represent the locations of stable diamagnetic levitation, in accordance with one or more aspects of the present invention;

FIGS. 6C and 6D depict a top view of one embodiment of the sets of corresponding grid points, X and Y of the set of complimentary tessellated magnetic stages of FIGS. 6A and 6B isolated, which represent the locations of stable diamagnetic levitation, in accordance with one or more aspects of the present invention;

FIGS. 7A and 7B depict a top view of one embodiment of a set of complimentary grid points, X and Y, which represent the locations of stable diamagnetic levitation, in accordance with one or more aspects of the present invention;

FIG. 7C depicts a top view of one embodiment of the union of the set of complimentary grid points, X and Y, for FIGS. 7A and 7B, which represent the locations of stable diamagnetic levitation and is complete grid-array, in accordance with one or more aspects of the present invention;

FIGS. 8A and 8B depict a top view of one embodiment of two completed grid-arrays, similar to those in FIG. 7C, in accordance with one or more aspects of the present invention;

FIG. 8C depicts a top view of one embodiment the two completed grid-arrays of FIGS. 8A and 8B joined via an offset in x and y to form a grid with increased density, in accordance with one or more aspects of the present invention;

FIGS. 9A and 9B depict a top view of one embodiment of a system to complete a grid-array including a set of complimentary tessellated magnetic stages with a set of diamagnetic components on both stages, in accordance with one or more aspects of the present invention;

FIG. 9C depicts a top view of one embodiment of a system shown in FIGS. 9A and 9B with a set of diamagnetic components from FIG. 9A assembled and subsequently affixed to a substrate by a transfer substrate, in accordance with one or more aspects of the present invention;

FIG. 9D depicts a top view of one embodiment of a system shown in FIG. 9C with the set of diamagnetic components from FIG. 9B assembled and subsequently affixed to a substrate by a transfer substrate with those from FIG. 9A, and then the second, complimentary set, affixed onto the same substrate completing the grid, in accordance with one or more aspects of the present invention;

FIGS. 10A and 10B depict a top view of one embodiment of a system to complete a grid-array including a set of complimentary tessellated magnetic stages with a set of diamagnetic components assembled thereon, in accordance with one or more aspects of the present invention;

FIGS. 10C and 10D depict a top view of one embodiment of the set of diamagnetic components of FIGS. 10A and 10B affixed to a transfer substrate respectively, in accordance with one or more aspects of the present invention;

FIG. 10E depicts a top view of the set of diamagnetic components of the transfer substrate of FIG. 10C affixed to a final substrate, in accordance with one or more aspects of the present invention; and

FIG. 10F depicts the set of diamagnetic components of FIG. 10D transferred from a transfer substrate and affixed to the substrate of FIG. 10E, completing the pattern, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

Generally stated, disclosed herein are methods and systems of designing and assembling tessellated magnetic stages for assembling diamagnetic components into a grid array using directed self-assembly. Advantageously, the methods and design allow for reduced assembly time enabling higher throughput, allowing for quicker design and implementation of devices, such as displays, including diamagnetic components, for instance light emitting diodes (LEDs).

Directed self-assembly (DSA) is a powerful tool used to arrange objects into a known configuration. Nano- and micro-scale DSA in the form of co-block polymers are used in semiconductor manufacturing to create periodic structures with dimensions less than conventional lithography can easily achieve. However, there is little work on DSA in the meso-scale: 100 μm-10 mm. The use of DSA with semiconductor devices on a magnetic stage where magnets are arranged in alternating “North up”/“South up”, checkerboard configuration can be utilized. The diamagnetic elements can be placed onto a vibrating stage and settle in stable levitation points at the intersections of these magnets, corresponding to magnetic potential wells. To ensure each well contains one diamagnetic element the total number of elements originally placed on the stage must be greater than the number of stable levitation points. Therefore, excess diamagnetic elements must move via vibration to the edge of the stage and fall off of it. As they move, the diamagnetic components follow a “random-walk” path. If a full “checkerboard” style stage were scaled to larger area, excess diamagnetic components in the center of the board could take an increasingly long time to reach the edge.

To overcome this challenge, disclosed herein is a “tessellated magnetic stage” design using sub-stages of the aforementioned “checkerboard” configuration together with openings including voids, or holes. The stage is designed to minimize the distance needed for excess diamagnetic components to escape the sub-stages, while populating approximately half of the overall grid. A second magnetic stage, which acts as a complement to the first, can then be used to assemble a complementing set of diamagnetic components, which once transferred, completes a grid-array of diamagnetic components.

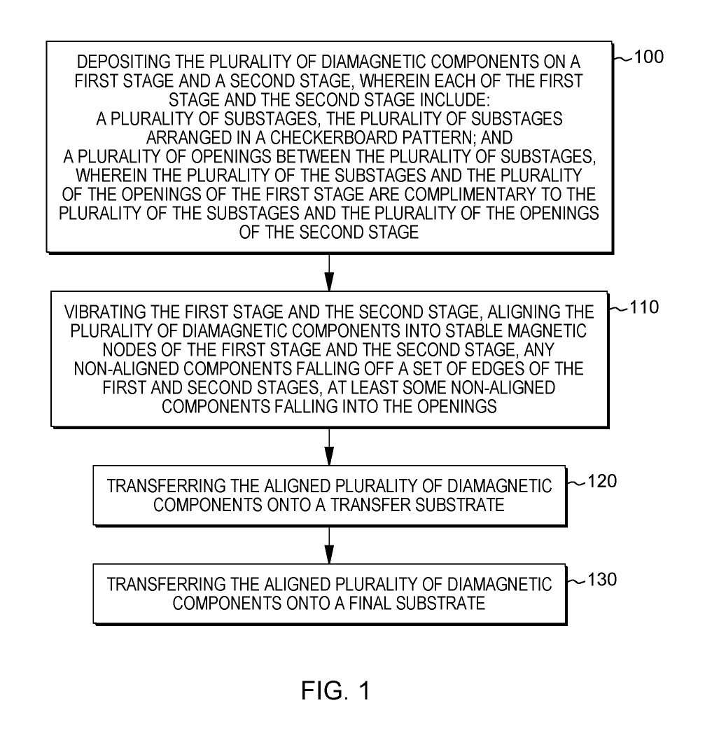

In one aspect, in one embodiment, as shown in FIG. 1, a method of assembling a plurality of diamagnetic components is disclosed, which may include depositing the plurality of diamagnetic components on a first stage and a second stage, wherein each of the first stage and the second stage include a plurality of substages, the plurality of substages arranged in a checkerboard pattern and a plurality of openings between the plurality of substages, wherein the plurality of the substages and the plurality of the openings of the first stage are complimentary to the plurality of the substages and the plurality of the openings of the second stage 100; vibrating the first stage and the second stage, aligning the plurality of diamagnetic components into stable magnetic nodes of the first stage and the second stage, any non-aligned components falling off a set of edges of the first and second stages, at least some non-aligned components falling into the openings 110; transferring the aligned plurality of diamagnetic components onto a transfer substrate 120; and transferring the aligned plurality of diamagnetic components onto a final substrate 130. The aligned diamagnetic components may be transferred directly to a final substrate from the first stage and the second stage.

Additionally, the aligned diamagnetic components of the first stage and the second stage may be each transferred to the transfer substrate prior to being simultaneously transferred to the final substrate. In some embodiments, the aligned diamagnetic components of the first stage and the second stage may each be transferred to a separate transfer substrate prior to being transferred to the final substrate. In further embodiments, the aligned diamagnetic components of the first stage and the second stage may each be transferred to the transfer substrate separately prior to each being transferred to the final substrate separately. The first stage and the second stage may then be offset from the original alignment, and the method carried out a second time, or any subsequent number of times, placing a second plurality of diamagnetic components on the final substrate, filling spaces between the first set of components, increasing the density of components. The components can include LEDs, and the final substrate may include a display or a portion of a display.

In the present invention, design rules for tessellated magnetic stages are outlined. Further embodiments are described below, and the methods disclosed above may be more readily understood by the descriptions of embodiments below.

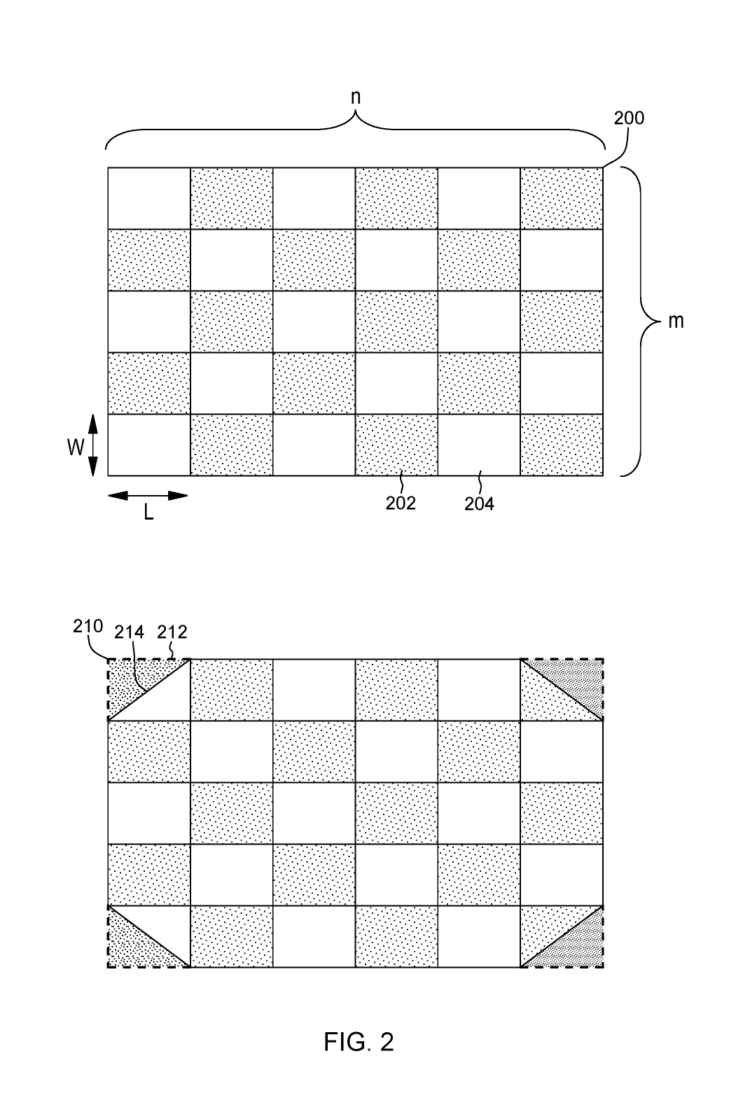

Turning to FIG. 2, in order to define the first and second stages, first is illustrated an example sub-stage 200, which may consist of rectangular grids of n×m magnets, where the integer numbers n and m are greater than 3. That is, the width and/or depth of magnets can include at least four magnets, and may include equal or different integers of magnets. The magnets have lateral dimensions L×W, which can include any dimensions. In some embodiments, these dimensions are approximately 1 millimeter (mm) by 1 mm. Thus, the sub-stages 200 have dimension n·L×m·W. These sub-stages are of the “checkerboard” configuration with magnets alternating “North up” 202 and “South up” 204 magnetics, which can include magnets, such as rare earth magnets, or magnetic fields generated in any way. The “unit cell” 210 of the tessellated stage consists of an n×m grid of magnets in the “checkerboard” configuration with approximately half of each corner magnet 212 removed along the diagonal to form an irregular octagon 214. Note, that this is only the “unit cell,” in reality when two unit cells are connected, the connected two halves on the corners of each unit cell 210 represent one whole magnet when combined. Similarly, at the edges of the stage, as described below, half-magnets may represent full magnets. The sub-stages 210 may be chosen or designed that the corners of the stages will include full magnets. In some embodiments, halves of like magnets may be joined, i.e. “North Up” with “North Up”. When constructing tessellated stages it may be necessary to rotate unit cells by 180 degrees at times to fit into the pattern. Each corner where four magnets meet includes a stable levitation node, or a magnetic node, where diamagnetic components may settle and remain.

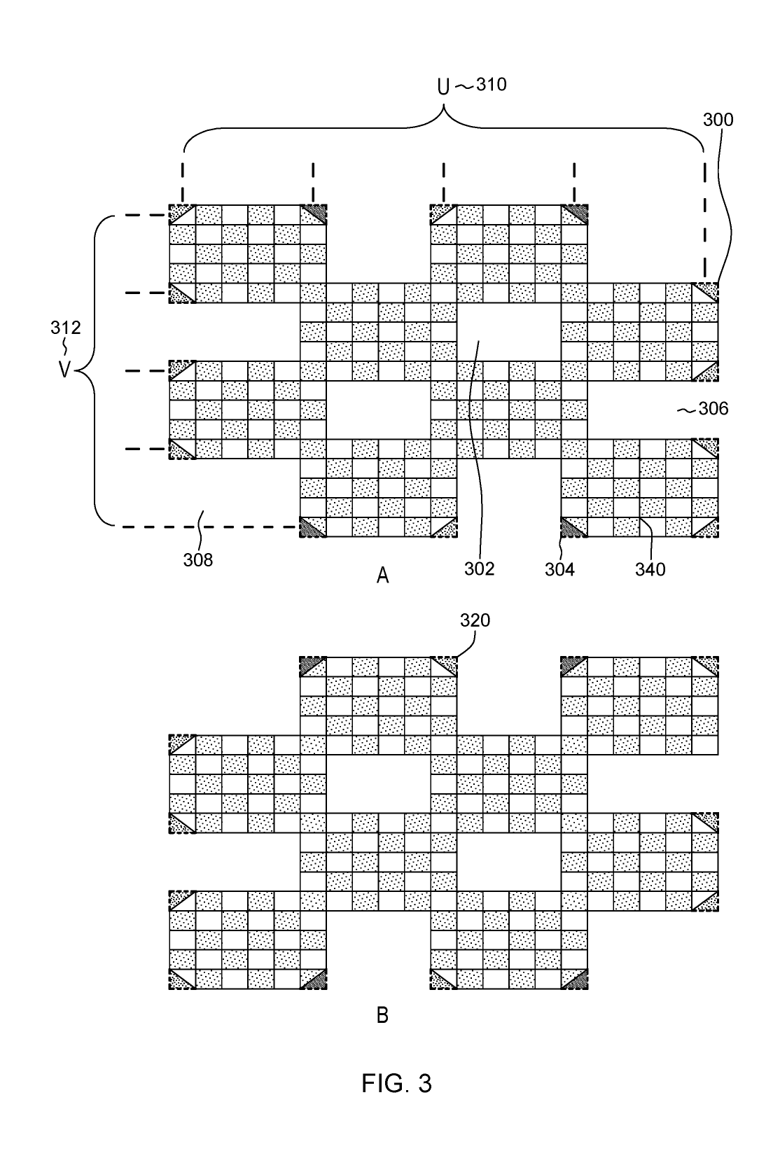

As seen in FIG. 3, an example in some embodiments of tessellated magnetic stages is illustrated. The tessellated first stage 300 is constructed by arranging sub-stages 200 (FIG. 2) into larger patterns, connecting the unit cells together by their beveled corners. In theory, these patterns could be any desired geometry, but in some embodiments takes a shape that is confined by a rectangle. The first stage 300 may have openings 302, 304, 306, and 308, i.e., internal open rectangular holes, which may be of varying sizes based on the geometry of the first stage 300. Opening 302 in central areas can have a dimension (n−2)·L×(m−2)·W, open areas at the edges 304 and 306 with dimension (n−2)·L×(m−1)·W or (n−1)·L×(m−2)·W respectively, and possible open areas at the corners 308 of dimension (n−1)·L×(m−1)·W. The openings 302, 304, 306, and 308 provide an outlet or escape for excess diamagnetic components collected on the first stage 300. The maximum distance needed to travel to reach an edge of the stage is thereby greatly reduced as compared to a solid stage, and hence, assembly time is reduced in reducing the time for random movement through vibrations to allow components to fall off of the first stage 300. The first stage 300 is categorized by the number of unit cells across (in the x-direction) 310, u, by the number of unit cells up (in the y-direction) 312, v. The final dimensions of the stage are therefore: (u(n−1)+1)L×(v(m−1)+1)W. Stable levitation or magnetic nodes 340 are illustrated as the points between four magnets, as described above.

A complementary magnetic tessellated stage, B, 320 in FIG. 3, may be formed to yield a set of points Y. In certain cases, this second stage can be generated by a transformation of the first stage, for instance either a rotation or a reflection. While described as a second stage 320, it should be understood that first stage 300 could be mechanically turned or flipped in some embodiments, requiring only a single stage. For the sake of clear description, two stages are described in the embodiments given below.

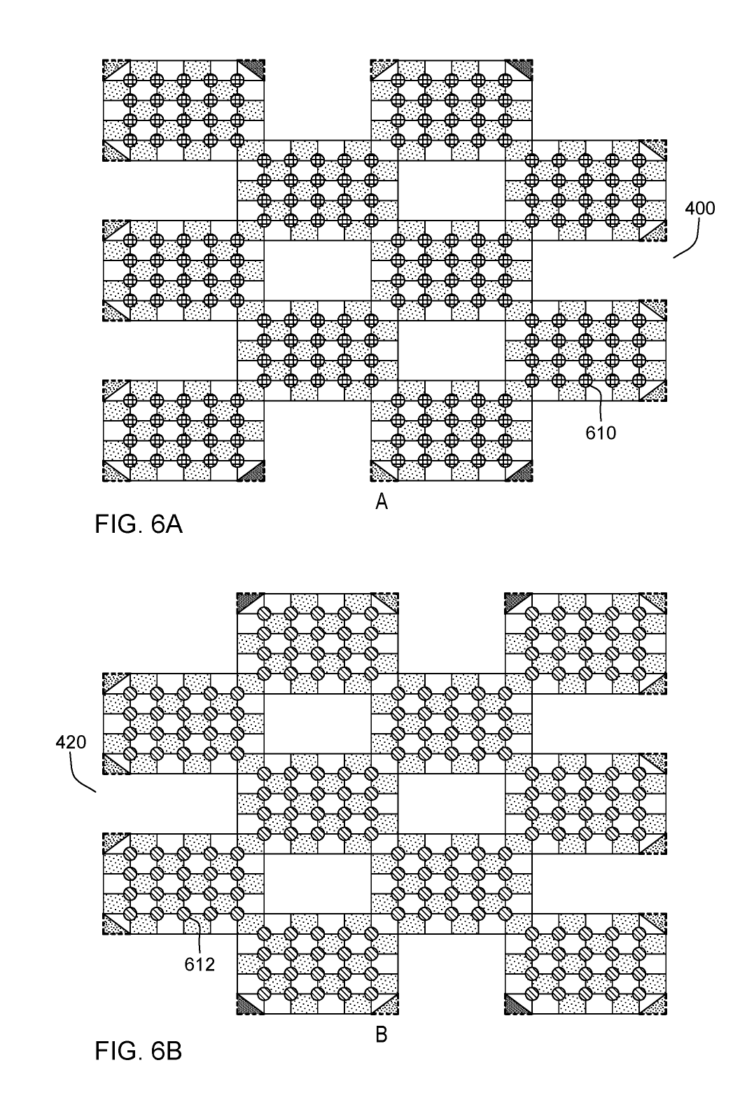

In one aspect, returning to FIG. 3, where u and v are both even, a reflection of the first stage 300, A, along the x or y axis will produce a second stage 320, B, capable of creating the complementary set of points Y (FIG. 6) to complete the grid.

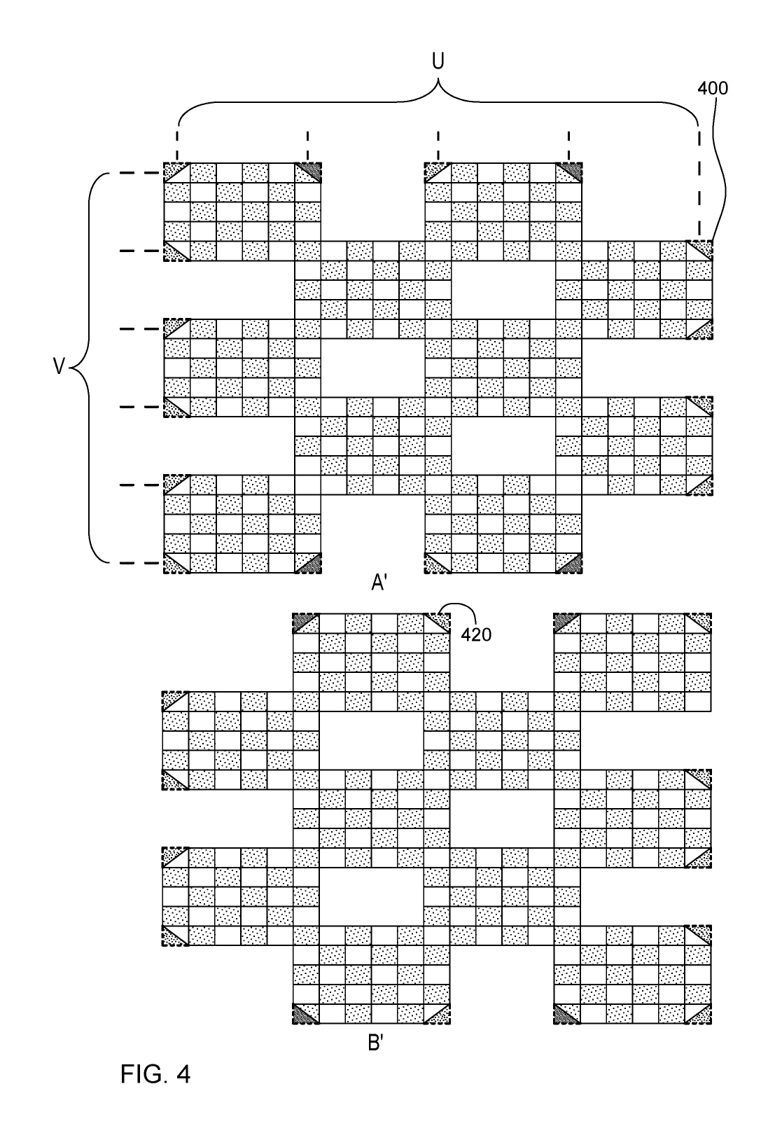

In another aspect, as shown in FIG. 4, where u and v are of mixed parity, then a rotation of the first stage 400, A′, by 180 degrees will produce a second stage 420, B′, capable of creating the complementary set of points Y to complete the grid.

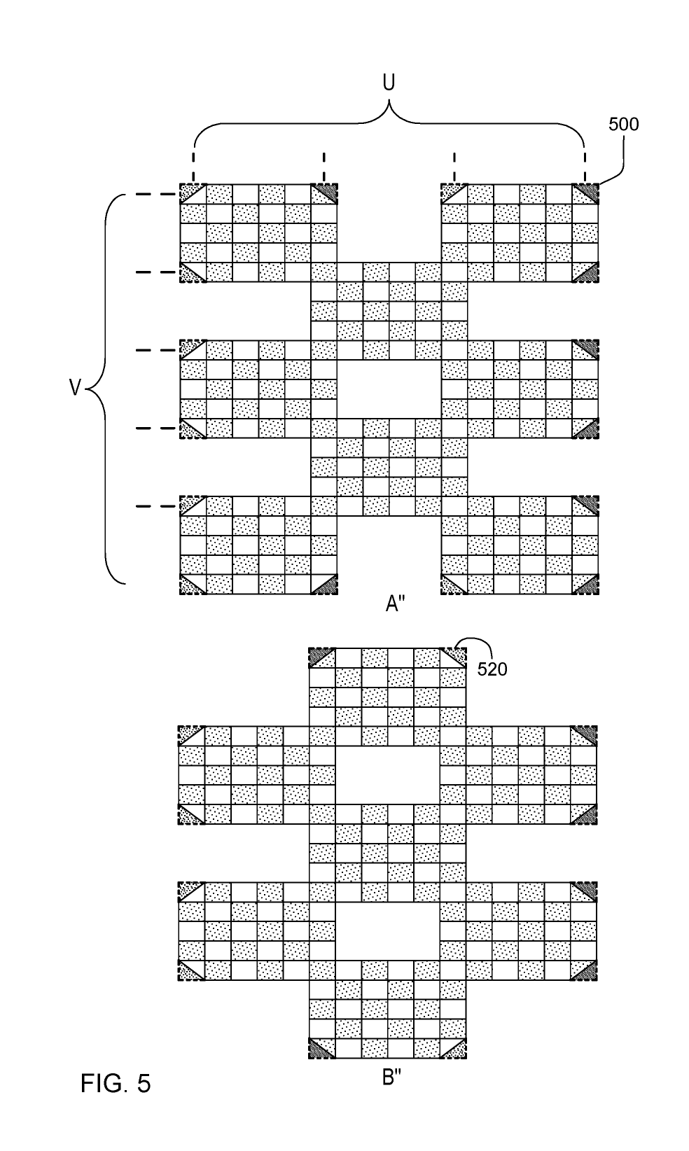

In another aspect, as shown in FIG. 5, where u and v are both odd, the second, complimentary stage 520, B″, may be constructed by assembling sub-stage unit cells in the locations of the open holes of the first stage 500, A″.

In some embodiments, these stages are used to assemble a plurality of magnetic components, or diamagnetic components, which can include LEDs or other components. Features of the stages are further described below in reference to methods and features of some embodiments.

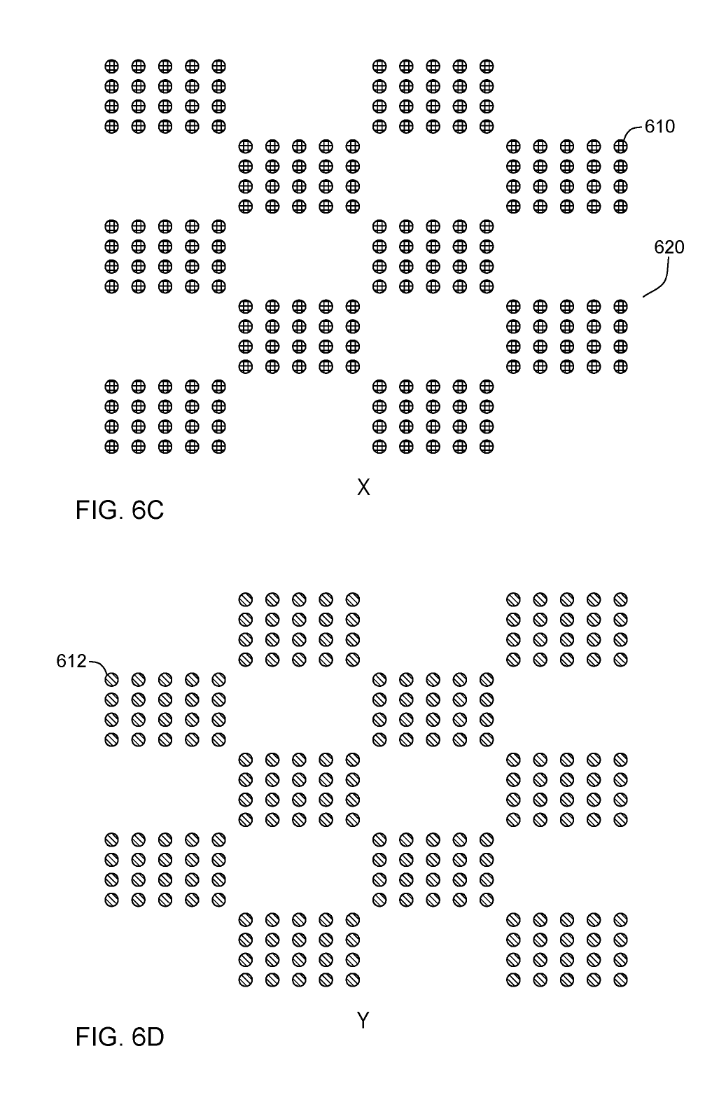

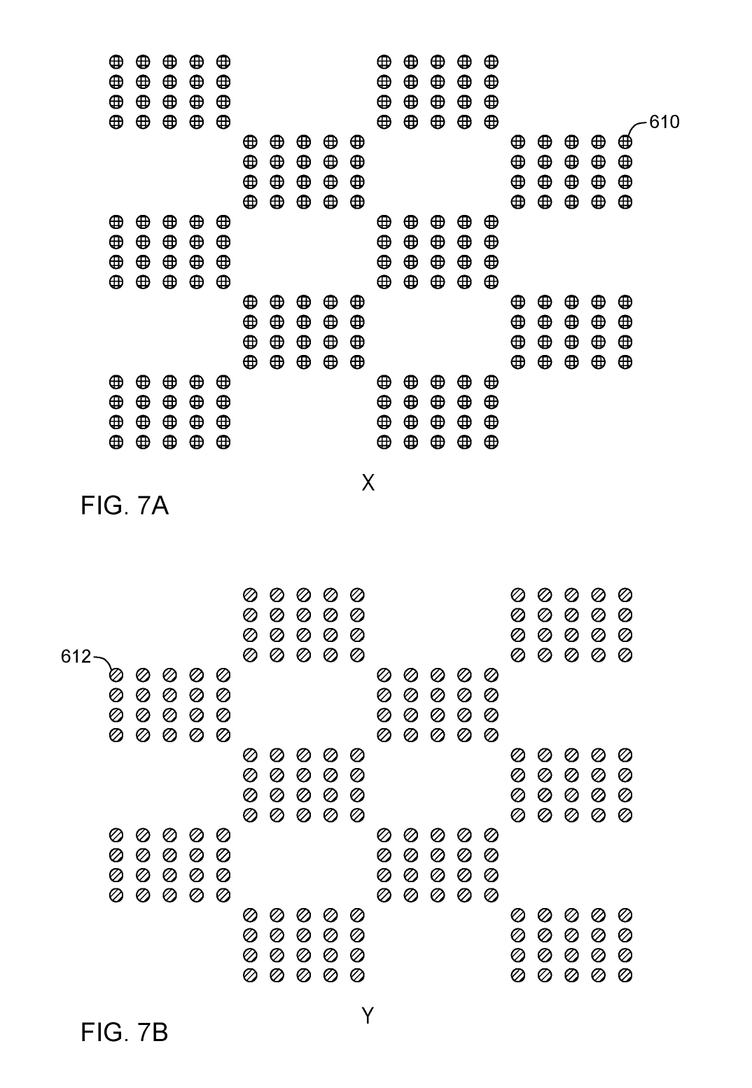

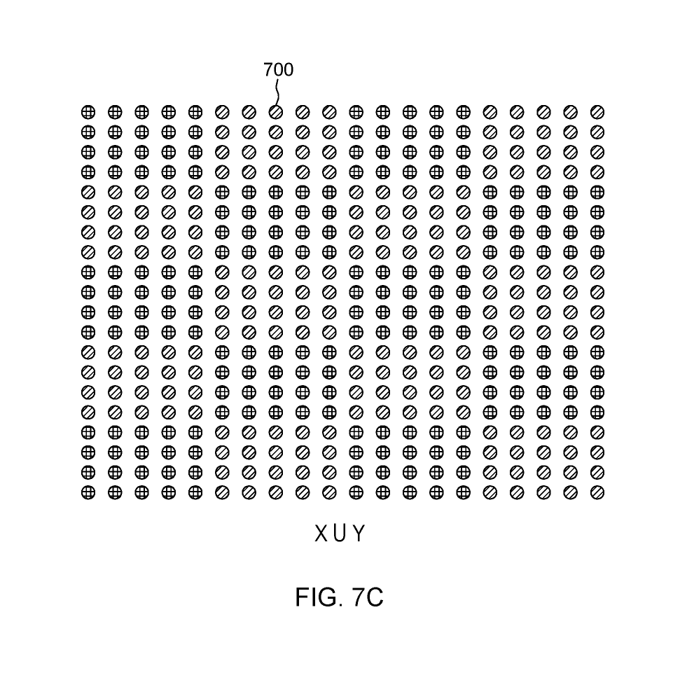

As seen in FIGS. 6A and 6B, when diamagnetic components are deposited onto the first stage 400 and second stage 420, in some embodiments during or before applying a vibration through a vibratory force source, they settle in stable levitation points at the intersections points of four magnets 340 (FIG. 3). This corresponds to the locations of magnetic potential wells. These points for first stage 400 include a set of points X 610. This set of points, X, illustrated in FIG. 6C, has open areas caused by the cut-outs and holes of the tessellated magnetic stage. A second set of points, Y 612, illustrated in FIG. 6D, of second stage 420 acts as a compliment to X FIGS. 7A and 7B depict a similar set of isolated magnetic potential wells formed by a set of complementary stages, with FIG. 7C depicting that that their union, X∪Y 700, as illustrated in the combined points of FIG. 7C, forms a complete grid of (n−1)u×(m−1)v points with dimensions L(n−1)u×W(m−1)v, as depicted in FIG. 7C. The vibration can be applied until the diamagnetic components illustrated as points are filled, and all excess diamagnetic components have fallen off of the stages, or have otherwise been removed. The aligned diamagnetic components are then transferred to a substrate, either a transfer substrate or a final substrate as described above, in any order disclosed therein. The substrate may include an adhesive and be brought into contact with the first stage 400 and the second stage 420, or the stages may be moved to come into contact with a transfer or final substrate.

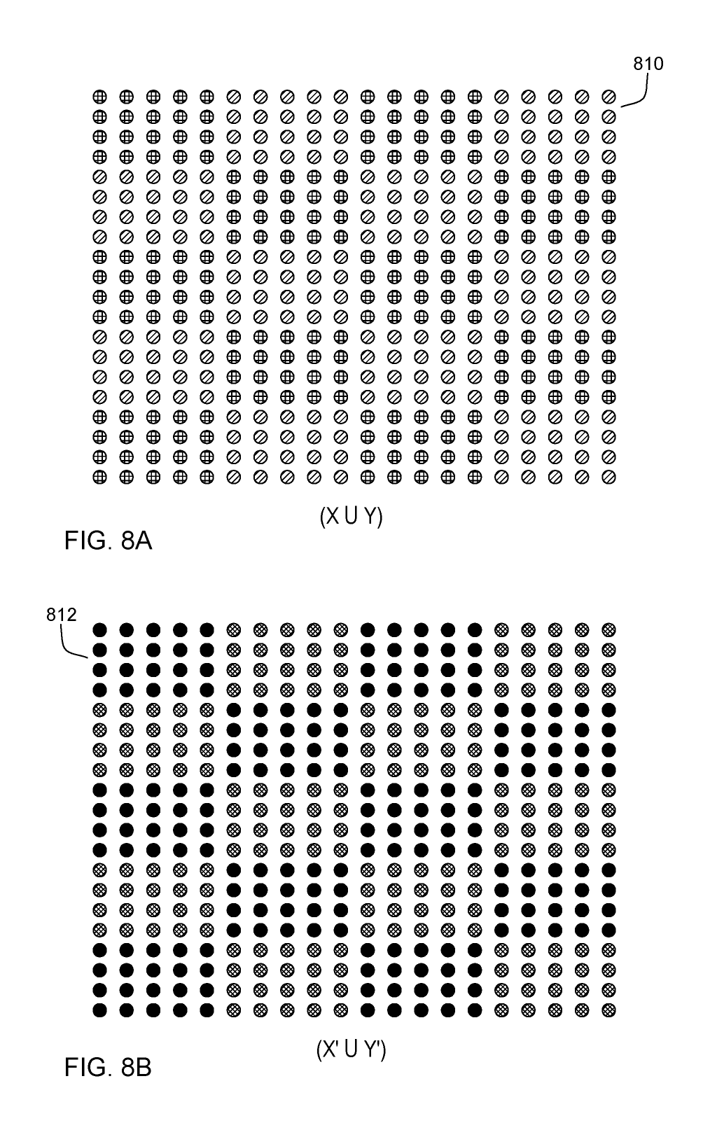

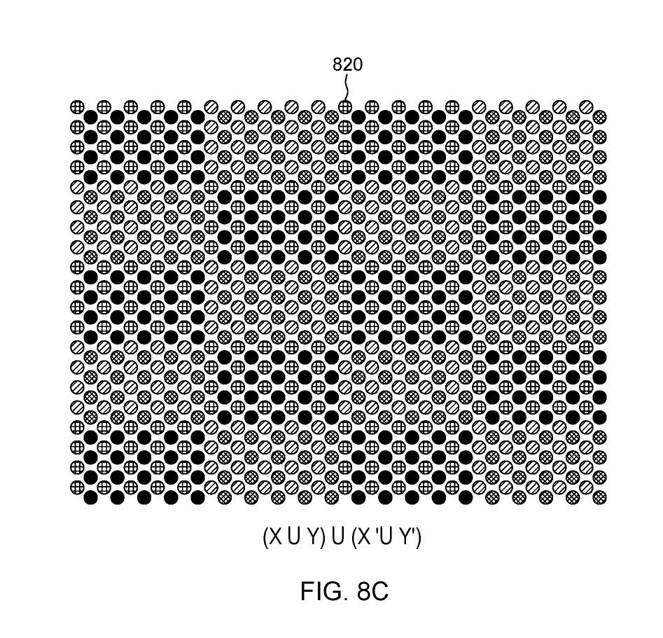

These sets of points represent the eventual locations of the assembled diamagnetic components, and their union represents a completed grid of such components after transfer. Thus it can be seen that the complementary second stage points fill all of the voids left by openings of the first stage. As seen in FIGS. 8A-8C, the process can be repeated twice producing two complete grids 810, depicted in FIG. 8A, which can be produced for example by the set of points in FIG. 7C, and 812 depicted in FIG. 8B, an offset of the set of points depicted in FIG. 7C. During final transfer the second grid 812 can placed offset from the first 812, in such a way as to produce a more dense grid 820, depicted in FIG. 8C as a combination of the set shown in FIG. 8A combined with the offset combination shown in FIG. 8B. In one aspect, the displacement is equal to ½L×½W. This process can be repeated as many times as desired, so long as the physical diamagnetic components do not overlap, in some embodiments.

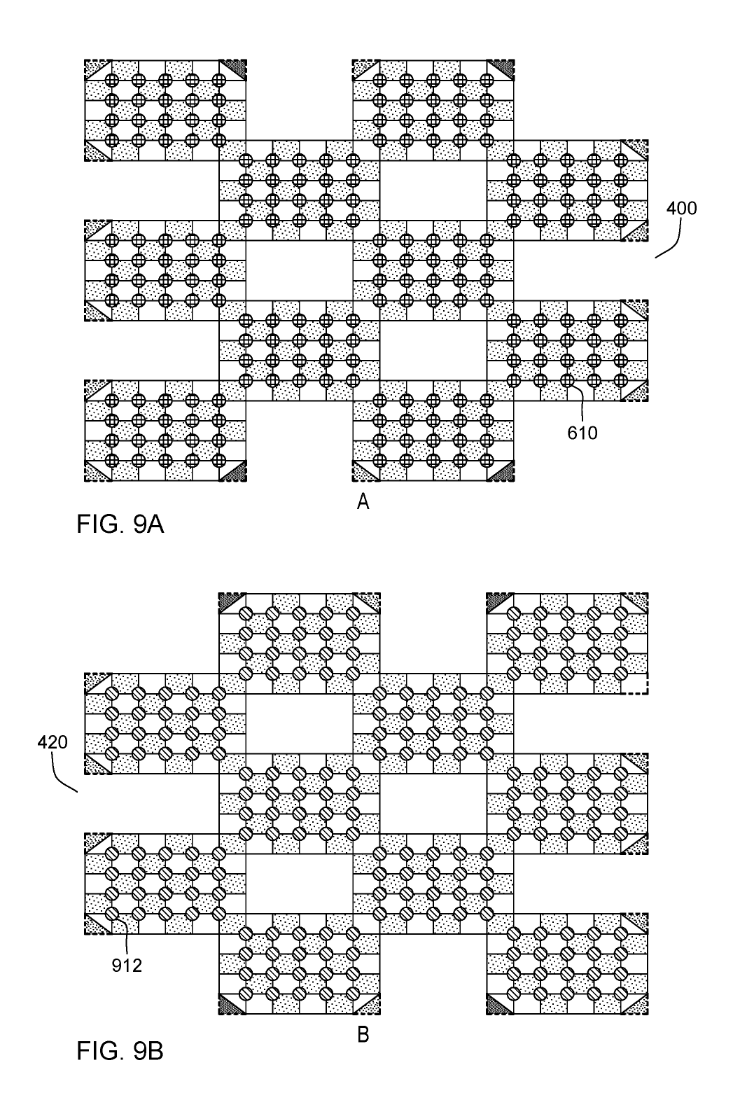

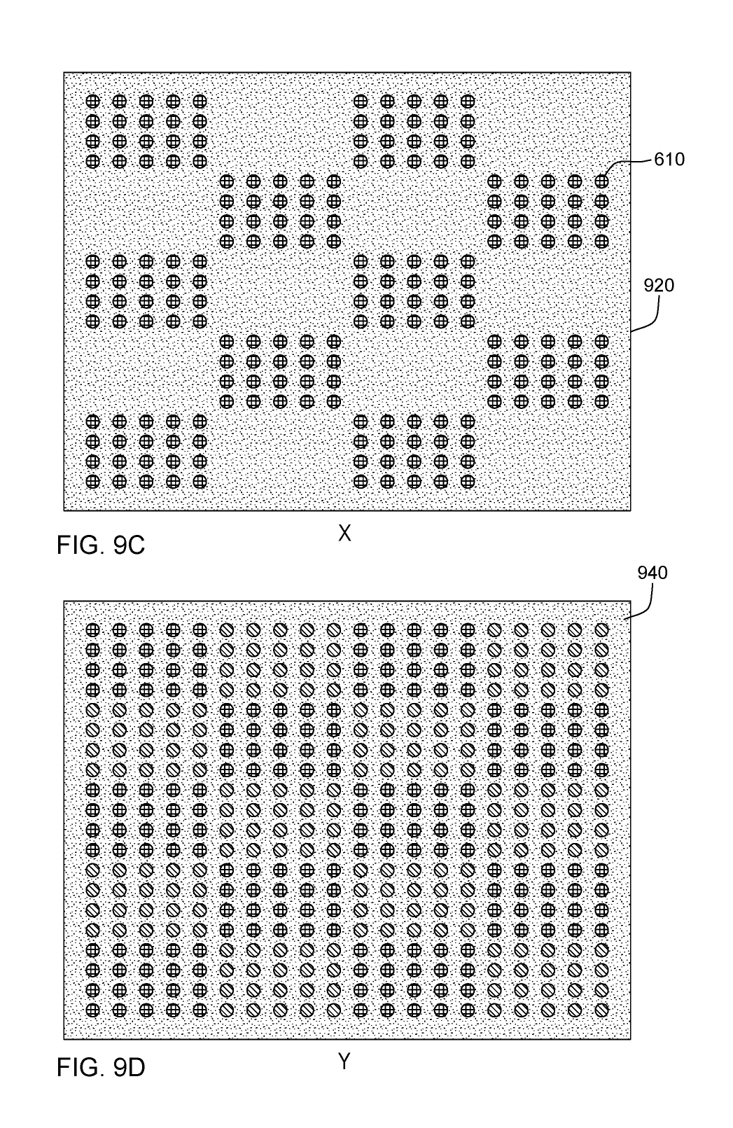

In one embodiment, as seen in FIGS. 9A-9D, after assembly, the diamagnetic components at locations defined by the set of points X 610 are affixed all at once, in a parallel fashion, to a transfer substrate 920. For instance, the components of FIG. 9A are affixed to transfer substrate 920 in 9C, followed by those of 9B being added to transfer substrate 920 in FIG. 9D. The transfer substrate 920 may be rigid or flexible, comprised of metal, glass, polymer, or other material known to those skilled in the art or later developed. In one aspect, the set of diamagnetic components can remain on the transfer substrate while more components are affixed to it from subsequent assembly stages 912, B, and added to the transfer substrate, 940. Then, once all the necessary components are affixed to the transfer substrate, they can all be deposited in parallel onto a final receiving substrate. In some embodiments, the steps shown in FIG. 9D can be repeated, for instance with an offset of both FIGS. 9A and 9B, making a denser set of components on the transfer substrate 940 prior to being deposited onto a final substrate.

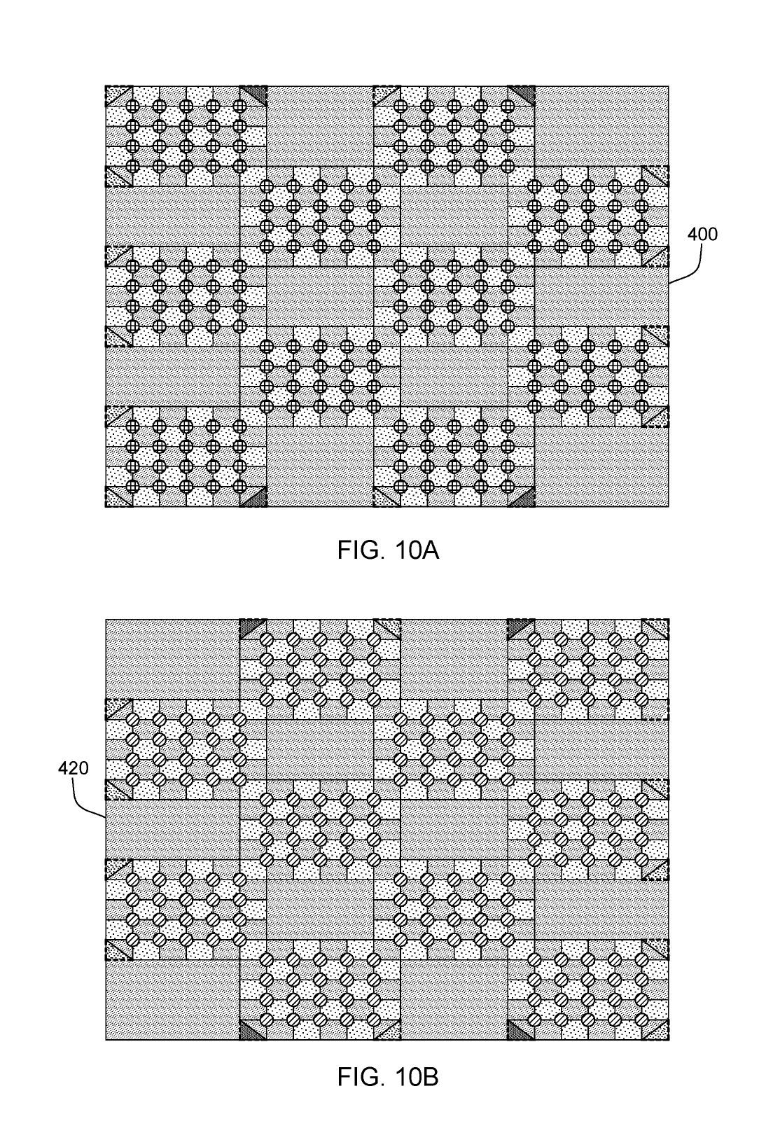

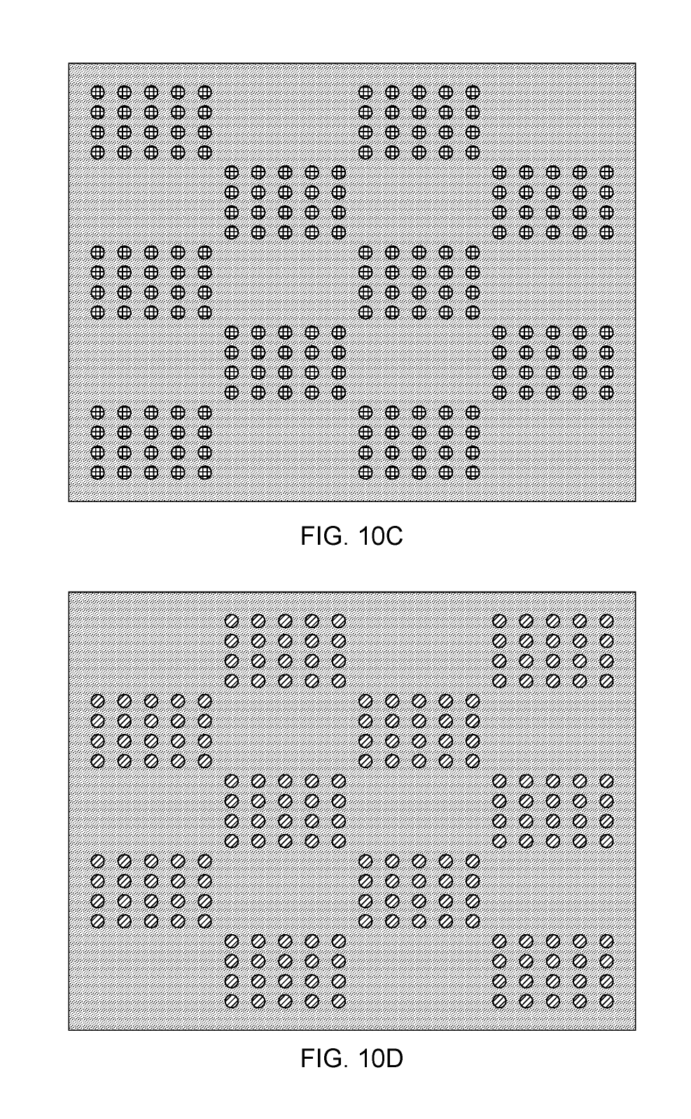

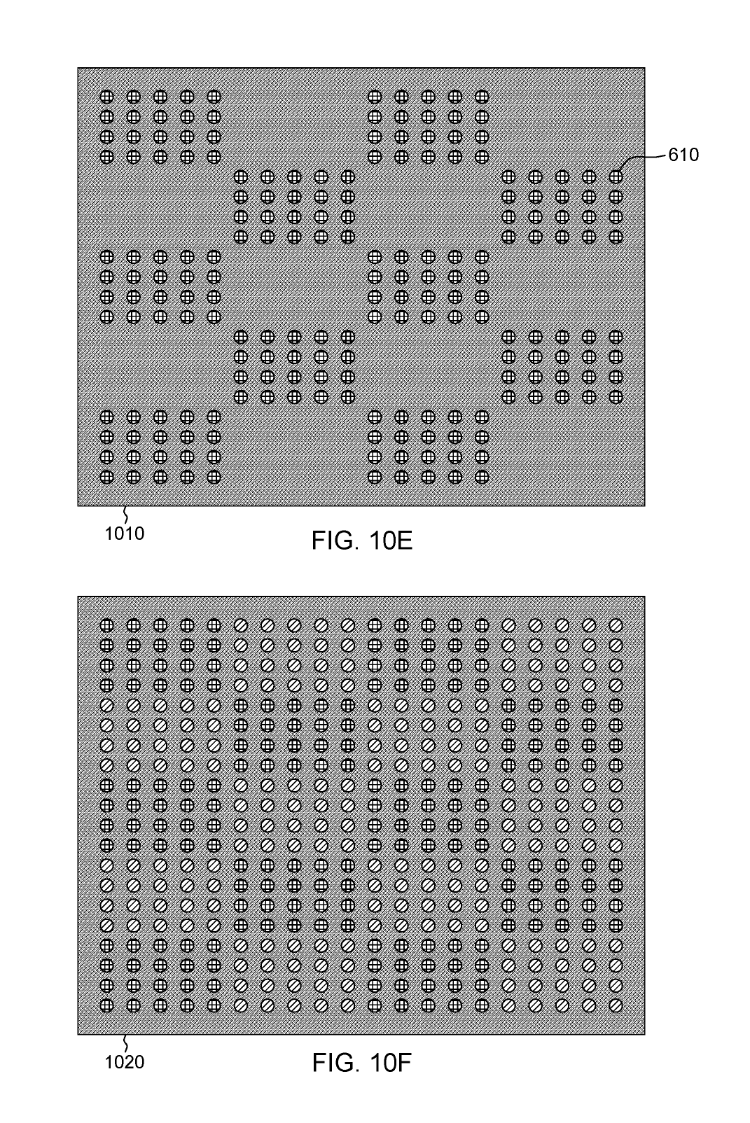

In another embodiment, as seen in FIGS. 10A-10F, the transfer substrate can deposit the set of diamagnetic components onto a final receiving substrate 1010 in individual steps, and the process may be repeated as many time as necessary or desired, and multiple pick-up/transfer/deposit steps can occur to add more sets of components to the final receiving substrate until the desired grid is complete 1020. For instance, the stages of FIGS. 10A and 10B are each individually picked up on a transfer substrate in FIGS. 10C and 10D. This can be done with multiple transfer substrates or by the same transfer substrate following deposition of the components in FIG. 10C, and then picking up those in FIG. 10D. As depicted in FIG. 10E, the components of FIG. 10C are deposited on final substrate 1010, and then those of FIG. 10D are added to the final substrate by the transfer substrate, as depicted in FIG. 10F.

Disclosed above are embodiments which include quick and efficient methods and systems for constructing a set of tessellated magnetic stages for complete grid assembly to reduce directed self-assembly time.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A system for assembling a plurality of diamagnetic components, the system comprising:
a first stage and a second stage, wherein each of the first stage and the second stage include:
a plurality of substages, the plurality of substages arranged in a checkerboard pattern; and
a plurality of openings between the plurality of substages, wherein the plurality of the substages and the plurality of the openings of the first stage are complimentary to the plurality of the substages and the plurality of the openings of the second stage.

2. The system of claim 1, wherein each of the plurality of substages includes a grid of magnets, the grid of magnets comprising a checkerboard pattern of a set of north up magnets and a set of south up magnets.

3. The system of claim 2, wherein each of the plurality of substages includes a rectangular shape with a width of at least four magnets.

4. The system of claim 3, wherein the substage includes a stable magnetic node in each corner where four magnets meet.

5. The system of claim 4, wherein each magnet on an outside corner of each substage is only a half magnet, forming a triangle on each corner magnet, and forming an irregular octagon of each substage.

6. The system of claim 5, wherein the first stage and the second stage include full magnets at intersecting corners of substages comprising a combination of the half magnets of the substages.

7. The system of claim 5, where the nodes of the first stage align such that the openings of the first stage are filled by the nodes of the second stage, creating a full grid pattern when an image of the first stage is aligned with an image of the second stage.

8. The system of claim 1, wherein the first stage has an even number of substages wide and an even number of substages deep.

9. The system of claim 8, wherein the second stage comprises a reflection of the first stage.

10. The system of claim 1, wherein the first stage has an odd number of substages wide and an odd number of substages deep.

11. The system of claim 10, wherein the second stage comprises the set of openings of the first stage being replaced by a set of substages, and the set of substages of the first stage being replaced by a set of openings.

12. The system of claim 1, wherein the first stage has one of an odd or even number of substages wide and the other of odd or even number of substages deep.

13. The system of claim 1, wherein the second stage comprises a copy of the first stage rotated 180 degrees.

14. A method of assembling a plurality of diamagnetic components, the method comprising:
depositing the plurality of diamagnetic components on a first stage and a second stage, wherein each of the first stage and the second stage include:
a plurality of substages, the plurality of substages arranged in a checkerboard pattern; and
a plurality of openings between the plurality of substages, wherein the plurality of the substages and the plurality of the openings of the first stage are complimentary to the plurality of the substages and the plurality of the openings of the second stage;
vibrating the first stage and the second stage, aligning the plurality of diamagnetic components into stable magnetic nodes of the first stage and the second stage, any non-aligned components falling off a set of edges of the first and second stages, at least some non-aligned components falling into the openings; and
transferring the aligned plurality of diamagnetic components onto a transfer substrate.

15. The method of claim 14, further comprising:
transferring the aligned plurality of diamagnetic components onto a final substrate.

16. The method of claim 15, wherein the aligned plurality of diamagnetic components of the first stage and the second stage are each transferred to the transfer substrate prior to being simultaneously transferred to the final substrate.

17. The method of claim 15, wherein the aligned plurality of diamagnetic components of the first stage and the second stage are each transferred to a separate transfer substrate prior to being transferred to the final substrate.

18. The method of claim 15, wherein the aligned plurality of diamagnetic components of the first stage and the second stage are each transferred to the transfer substrate separately prior to each being transferred to the final substrate separately.

19. The method of claim 15, wherein the first stage and the second stage are realigned offset from an original alignment, and the method is repeated to place a second plurality of diamagnetic components in a set of spaces between the plurality of diamagnetic components.

20. The method of claim 14, wherein the plurality of diamagnetic components comprises a plurality of LEDs.
